(19) United States
(12) Patent Application Publication
(10) Pub. No.: US 2015/0382496 A1
(43) Pub. Date: Dec. 31, 2015

(54) ELECTRONIC DEVICE AND BATTERY ENCLOSURE

(71) Applicant: RICHARD BURANT, JR., HARTLAND, WI (US)

(72) Inventor: RICHARD BURANT, JR., HARTLAND, WI (US)

(21) Appl. No.: 14/247,335

(22) Filed: Apr. 8, 2014

Related U.S. Application Data
(60) Provisional application No. 61/813,662, filed on Apr. 19, 2013.

(51) Int. Cl. H05K 7/02; H02B 1/20; G08B 21/18; H02B 1/32; H05K 7/20; H05K 5/02; H02B 1/30

(52) U.S. Cl. CPC H05K 7/023; H05K 5/0247; H05K 5/0213; H02B 1/20; H02B 1/305; H02B 1/32; H05K 7/2039; H05K 5/0208; G08B 21/185

(57) ABSTRACT

The present invention provides for a low cost, light weight, high strength earthquake certified power and equipment enclosure module which provides for an effective housing of DC batteries allowing for simultaneous dual voltage functionality with intelligent evacuation of thermal and toxic residuals. Stacking and interlocking the modules provides an environment for housing diverse electrical components making the invention enclosure invulnerable to obsolescence. Intuitive disassembly and reassembly allows the cabinet modules to be moved easily too hard-to-reach locations eliminating the need for costly cranes, lifts or excessive man-power. The design delivers the smallest footprint with the highest power density, embedded alarming and thermal management ensures safety in operation.

### CROSS-REFERENCE TO RELATED APPLICATIONS

This application claims the benefit of U.S. Provisional Application No. 61/813,662 filed on 19 Apr. 2013 the entire contents of which are incorporated herein by reference.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### FIELD OF THE INVENTION

The present invention relates generally to housing of electronics and power systems in the data, voice and digital content industries. More particularly, the present invention is modular, stackable enclosure capable of accommodating various electronics and batteries in a significantly reduced footprint and, in that, characterized in having integrated means for allowing a dual voltage utility while enhancing safety as well as thermal management efficiency.

### BACKGROUND OF THE INVENTION

Recent strides in the field of electronics have made possible the ability to package more processivity, more power and more functionality into ever smaller spaces leading to the advent of specialized equipment, which in turn, have mandated special needs of back-up power, design, construction, packaging, housing, operations and maintenance.

Today, for functional as well as aesthetic reasons, we find that electrical equipment and their components are commonly contained within various types of housing such as cabinets or enclosures. In such closed spaces, thermal residue or heat buildup due to highly functional components including high intensity communication equipment, fast processors, high capacity batteries and so on quickly escalates into a problem area and, over time, potentiates consequences including compromised reliability or premature failures of equipment. Therefore, in case of sensitive electronic systems that generate heat as result of their operations or need to operate in proximity of other heat-extruding systems, it is extremely crucial to both avoid temperature buildups and maintain a critically stabilized uniform thermal profile in the contained spaces.

As may come naturally to a person of average skill in the art, the heat generated by electronic devices and circuitry must be dissipated to improve reliability and prevent premature failure. Attempts to address the aforementioned needs find mention in the art.

Prior art, to the extent surveyed, bears scattered references to heat dissipation technologies such as forced air cooling, use of heat sinks, convective air cooling, integration of air flow design elements in construction of housings to chaperone natural ventilation and so on. However, widespread applicability of these technologies has been marred due to presence of their inherent disadvantages and deficiencies including, but not limited to, short lifecycles, inability to achieve uniform temperature stabilization in compact or crowded enclosures and high resource costs to build, assemble and run. Another shortcoming of these technologies is that many themselves need power to operate, thus increasing the energy footprint of the system while being of no use during power outages.

CA 2014682 discloses a battery plant system comprised of an array of unit battery cells designed to interlock with each other. The interlocked unit cells are electrically connected to create battery cell assembly modules of the desired voltages and the interlocked unit battery cells are mounted on a multiple unit battery cell support member to form a battery cell assembly module. U.S. Pat. No. 5,140,744 relates to the design of a modular multicell battery and rack system which may be assembled to fit various floor space and height requirements by using standardized multicell modules having keyed connectors. However, these system designs are intended specifically for indoor operation and capable of providing only a single voltage at a time. Further, there is no cabinet provided with integrated control or ventilation means for management of the thermal output. The interlocking battery system disclosed additionally has no safety features such as door-open alarm, stacking ability and no dual voltage capability, thereby limiting its utility in the application environment targeted by the present inventor

U.S. Pat. No. 5,806,948 relates to a retrofit battery cabinet for telecommunications equipment wherein a 48 volt DC or other battery power supply is held in a battery cabinet to provide a battery power supply to telecommunications cabinets. Ventilation is provided by exhaust fans which channel air to flow through the full-length front vent at base of a removable door to a subterranean or other thermal reservoir for maintenance of constant-temperatures. An intrusion alarm is also provided which may alert a central monitoring station or control of removal of the front door panel. However, this design is not without its share of shortcomings—specifically, this cabinet is not stackable, the battery system does not provide dual voltage functionality.

CA 2371374 relates to an outdoor equipment cabinet enclosure designed to dissipate heat generated by electrical components housed therein including an upper chamber for housing the components and a lower chamber configured to store banks of batteries for a stand-by power supply system. A lower wall separates the batteries from the electronic components. A heat exchanger is disposed in the upper chamber and includes intake and exhaust ports for creating a circulating air flow path through outer columns of the heat exchanger for interior air within the upper chamber. An air flow passageway is defined by the lower wall and the upper surfaces of the batteries. A pair of diverters located in the outside air flow passageway deflect the outside air flowing across the upper surfaces of the batteries through spaces between the batteries. A pair of opposed baffles help direct the outside air flow ton an inner column of the heat exchange and also include portion serving to locate and retain the batteries. This design however, is not stackable and not capable of provisioning for dual voltage capabilities, thereby leaving a persisting need for a new design that meets these requirements.

Among recent art, US 20140036442 discloses a stackable outdoor modular electronic cabinet for housing telecommunications equipment which has integrated sub-systems for thermal and interface management. However the stackable modules are located within the outdoor enclosure framework and cannot themselves be placed into an outdoor environment, the cabinet system does not support dual voltage and is an extremely large cabinet that itself needs large amounts of electrical power to manage the thermal management system. The cabinet system cannot be dismantled and hand-carried to a rooftop and reassembled due to its large exoskeleton besides being costly to produce and dispose.

It shall be understood that the background description provided herein before is for the purpose of generally presenting the state of art in the field of the present invention and generally the needs unaddressed. The information, admissions and shortcomings presented are not exhaustive. Work of the presently named inventor, specifically directed against the technical problems recited hereinabove and currently part of the public domain, is neither expressly nor impliedly admitted as prior art against the present disclosures.

In the telecom industry, clean, uninterrupted supply of backup power is crucial for enabling seamless network integrity, voice/data transfer and telemetry. In the event utility power is interrupted, the backup power must intervene in a lossless manner without power fluctuations or momentary lapses which would otherwise cause the electrical equipment to trip causing the end user customer to lose voice communication lose internet and IP address connectivity and machine to machine telemetry. Large arrays of DC batteries thus need to be maintained to serve backup power. From teachings of the art, it is known that capacity of these batteries to provide backup power and current output decreases with fluctuating temperatures within the cabinet. Further, during operation and charging, batteries emit potentially explosive hydrogen gas and its byproducts, which must be evacuated from the cabinet. As the reader may now appreciate, there exists a need for a cabinet design which furthermore provides for evacuating toxic fumes in addition to the thermal residue. An allied aspect of battery cabinet design is that commonly observed architectures are dedicated to one structural configuration or one voltage configuration or type of batteries, leading to virtual non-adaptability between operational platforms requiring different backup power specifications or designs. This results in hardware obsolescence whereby unnecessary replacement costs are incurred while upgrading or migrating the load and/or voltage requirements. It would be furthermore advantageous for such battery cabinet design to be universal in supporting housing as well as electrical and safety requirements of wired and wireless telecommunications equipment. No single prior art reference surveyed by the present inventor addresses these specifications in a comprehensive manner.

In view of the foregoing problems and shortcomings of existing solutions proposed, the need to devise an effective enclosure for batteries which addresses all the problem areas mentioned herein above yet persists. The present inventors, in understanding said needs, have undertaken focused research and come up with novel solutions to address the same. The following narration presents one exemplary way of performing the present invention.

### OBJECTS OF THE PRESENT INVENTION

Principal object of the present invention is to provide for construction and deployment of a cabinet module which effectively provides for stably housing electronic components capable of extruding a large amount of heat and/or toxic fumes.

Yet another object of the present invention is to provide a cabinet module which is capable of housing a wide variety of battery configurations amenable to different load and coexisting, simultaneous voltage requirements.

Yet another object of the present invention is to provide a cabinet module having interlocking means and thus, capable of existing as a standalone unit amenable to stacking multiple cabinet modules based on the specific customer requirements for housing electrical equipment.

Yet another object of the present invention is to provide a cabinet module which is so designed to facilitate a stacking capability to multiple to minimize the equipment footprint.

Yet another object of the present invention is to provide a cabinet module which is so designed to facilitate stacking capability without cranes or other hoisting equipment.

Yet another object of the present invention is to provide a cabinet design intended to be hand assembled and yet preserving the aesthetics and functional airflow necessary to thermally condition the cabinet system so provided.

Still another object of the present invention is to provide a modular cabinet design capable of standing on its own footprint without the means of support from an outdoor cabinet or exoskeleton.

Still another object of the present invention is to provide a cabinet module characterized in having low costs of materials, assemblage, maintenance and operations.

Still another object of the present invention is to provide a cabinet module characterized in having the ability to be used as-is, at the outset, in a non-stacked configuration and yet retain ability to be stacked at a later date without any modifications or alterations to its design.

A better understanding of the objects, advantages, features, properties and relationships of the invention will be obtained from the following brief description set forth in an illustrative embodiment and which is indicative of the various ways in which the principles of the present invention may be employed.

### SUMMARY OF THE INVENTION

This Summary is provided to introduce a selection of concepts in a simplified form that are further described below in the Detailed Description. This Summary is not intended to identify key aspects or essential aspects of the claimed subject matter. Moreover, this Summary is not intended for use as an aid in determining the scope of the claimed subject matter.

The present invention is directed towards an enclosure for electronic devices and batteries capable of supporting simultaneous dual voltage requirements of multiple electronic hardware platforms as typically observed in various application environments of the telecommunications industry and characterized in having means for allowing the enclosures to be stacked and, in that, extending integrated facilities for simultaneous dual voltage output and thermal/emissions management. Lateral benefits of the proposed design include reduced costs, skills and time investments for installation, operations and maintenance. Additionally the invention includes intelligent thermal control operative intra- and/or inter-module(s)/stacks via airflows channeled through connecting ventilation ductwork.

### BRIEF DESCRIPTION OF THE DRAWINGS

FIGS. 1(a to d) are front perspective, left side, right side and back views respectively of the enclosure in accordance with the present invention.

FIG. 2 illustrates internal construction and assembly of the enclosure in accordance with the present invention

FIG. 3 illustrates scheme of implementation of the unit enclosure in accordance with the present invention in a 2×3 stacked configuration.

FIG. 4 is a schematic for illustrating connections for grounding of enclosure at base of each stack shown in FIG. 3

FIG. 5(a and b) are a schematics for illustrating bus bar design for first shelf RTN bus bar single voltage and second shelf RTN bus bar single voltage

FIG. 6 is a schematic for illustrating routing and attachment of the fuse alarm cable to the fuse alarm switch in the module 000#1

FIG. 7 is a schematic for illustrating routing of the fan power cable in the hatch of module 000#1

FIG. 8 is a schematic for illustrating routing of fan power and temperature sensor cable in the hatch of module 000#1

FIG. 9 is a schematic for illustrating routing and attachment of the intrusion alarm cable to the alarm switch in the module 000#1

FIG. 10 is a schematic for illustrating routing and attachment of the intrusion alarm cable to the alarm switch from module 000#2

FIG. 11(a to c) are schematics for illustrating routing and return of DC power cable and configuration of bus bar connections in the module (000) for same voltage on each shelf (+24 V or −48V same voltage both shelves)

FIG. 12(a to c) are schematics for illustrating routing and return of DC power cable and configuration of bus bar connections in the module (000) for different voltage on each shelf (+24 voltage on one shelf & −48V voltage on second shelf)

FIG. 13(a) is a schematic for illustrating interconnections from module 000#1 and 000#2 in a single voltage configuration

FIG. 13(b) is a schematic for illustrating interconnections from module 000#1 and 000#2 in a simultaneous dual voltage configuration

FIG. 14(a) is a right side internal schematic view for illustrating DC interconnections from 000#3 and 000#2 to 000#1 in a single voltage configuration

FIG. 14(b) is a left side internal schematic view for illustrating interconnections for return bus from 000#3 and 000#2 to 000#1 in a single voltage configuration

FIG. 14(c) is a right side internal schematic view for illustrating DC interconnections from 000#3 and 000#2 to 000#1 in a simultaneous dual voltage configuration

FIG. 14(d) is a left side internal schematic view for illustrating interconnections for return bus from 000#3 and 000#2 to 000#1 in a simultaneous dual voltage configuration

FIG. 15 is a schematic for illustrating the wiring overview of interconnections from 000#3 and 000#2 to 000#1 of one stack to 000#1 of adjoining stack

FIG. 16 is a schematic for illustrating the airflow pattern intended for thermal management of the stack shown in FIG. 3

FIG. 17 is a schematic for illustrating the connections and affixtures between enclosures stacked as shown in FIG. 3

### DETAILED DESCRIPTION OF INVENTION

In this respect, before explaining at least one embodiment of the invention in detail, it is to be understood that the invention is not limited in its application to the details of construction and to the arrangements of the components set forth. Also, it is to be understood that the phraseology and terminology employed herein are for the purpose of description and should not be regarded as limiting. Overall, the purpose of the present invention is to solve aforesaid problems in existing art by incorporating all advantages of prior art and none of its disadvantages.

Telecommunication sites today are evolving into large power micro-cells, large power macro-cells, large power data centers, making extensive use of electronics and electrical equipment. Present DC distribution and installation practices, however, are expensive so far as resource investments of time, costs and skills are concerned. Smart utility cabinet design has been a forerunner among solutions proposed to address said concerns. Several factors need to be taken into consideration in designing an appropriate outdoor-rated cabinet as nature of equipment's to be housed, external environmental conditions, specifications of interfaces, cabling and so on. Prior art telecommunications cabinets have not been designed from the start to accomplish this functionality and flexibility Therefore, the art lists many different custom cabinet configurations that satisfy requirements of a particular telecommunications site, but redundant for other sites. Such custom manufacture always is associated with higher costs, fast obsolescence of components being discontinued, and lack of knowledge among installation/repair crews among other undesirable attributes. Accordingly, the present invention is directed towards achieving the objectives set forth above, but also reaching a generic design which is applicable across various application environments, electronic and electrical specifications. The following narration presents a yet preferred embodiment of the present invention.

In accordance with principles of the present invention, the unit equipment cabinet module, unit equipment and battery cabinet module, and battery cabinet module, in the presently preferred embodiment, comprises an outer shell enclosing an equipment/battery cabinet inner structure supporting two individual shelves each holding up to 4 individual 12 volt DC batteries. Typically the battery cabinet connects the batteries together into either a 12 VDC, 24 VDC, 36 VDC or 48 VDC string of batteries. The batteries are tied together and fused/circuit breakers are provisioned to protect the batteries, other electronic equipment or the user from electric shock or shorting.

Having generally specified the hardware outlook of the proposed battery cabinet module, it would be now beneficial to direct the reader towards that the inventive feature of the present invention lies in pioneering integration of innovative construction, deployment and operational elements which synergize to constitute a stacked battery plant which is easy to manufacture and assemble, operable across simultaneous dual voltages and yet scores low on carbon/heat foot prints throughout its lifecycle thus proving merit as a green technology.

Features of stackability and being assembled by hand without losing on aesthetic and/or functional attributes is made possible by placing high strength steel inner structures locked and bolted together to form the stackable skeleton equipment structure. Outer aluminum cabinetry provides the aesthetics and functional airflow necessary to thermally condition the different modules. Thus the modular cabinet design proposed herein is capable of standing on its own footprint without the means of support from an outdoor cabinet or exoskeleton and also capable of surviving the harsh environment and certified to withstand zone 4 earthquake shock and vibrations.

Modularity of design and assembly according to the narration set out above enables easy assembly/disassembly of the individual cabinet modules for hand carry to rooftops or tight areas with intuitive reassembly of the module. This feature eliminates the need for the costly rental of lifting cranes, closing of roads to deploy lift equipment, rental of barricades, police, security personnel, related insurance premiums due to safety concerns and logistic challenges. The cabinet itself has been designed from the beginning to be lightweight and modular incorporating a high strength steel skeleton with aluminium all weather exterior typically costing a fraction of similar cabinetry used in the industry today.

The cabinet module proposed herein is also characterized with the ability to be stacked at a later date. Typically, a user deploys a cabinet equipment system to support the current configuration needs of the user's application. Inevitably, the users load requirements change due to evolving technology which creates a need for more power, larger back-up needs and increased thermal management. The cabinet module proposed herein allows the user to add additional module/s at a later date while still maintaining the ability to add additional simultaneous dual voltage functionality, additional equipment space and combining the thermal conditioning from the previously placed modules all in a single footprint. This functionality is not available with conventional legacy cabinetry designs.

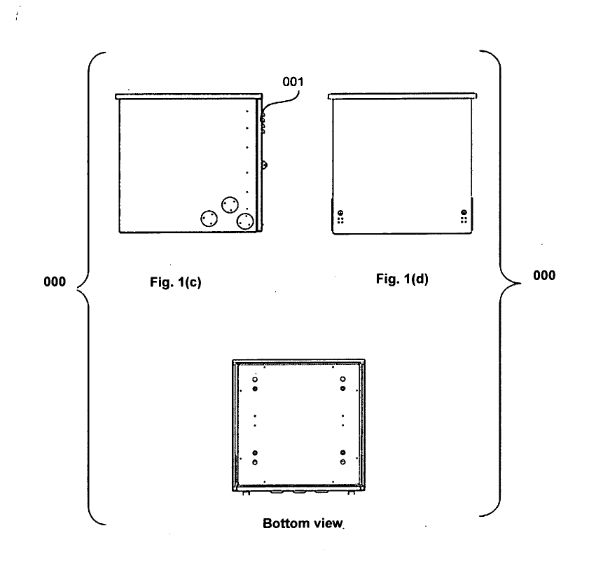

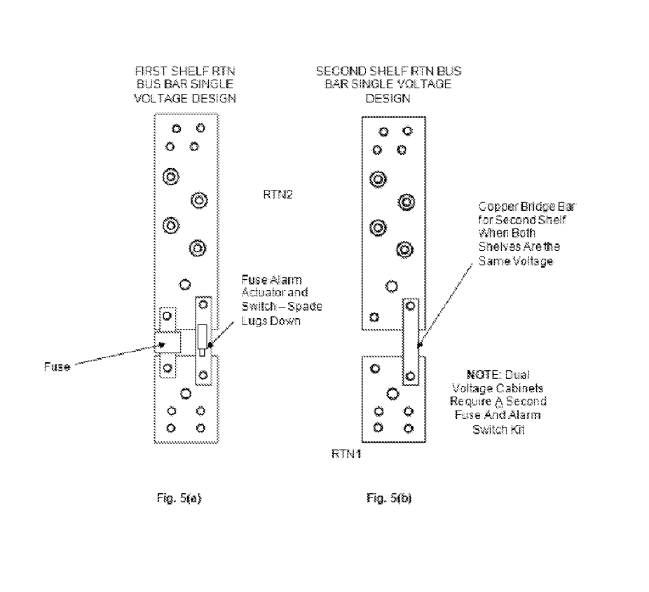

FIGS. 1(a to d) are front perspective, left side, right side and back views respectively of the enclosure module represented by (000) made in accordance with the present invention. Each module (000) has two battery shelves (not shown in the drawings in drawings) to which access is gained by opening the front door hatch (001) bearing two padlock latch assemblies 006 and 007 of each individual module represented by 000. As shown in FIG. 4, each base module (000) contains termination points (002) and (003) for load and return circuits. Alternatively, +24 VDC load and 24-V Return or −48 VDC load and 48 VDC return are made available as required for each shelf of module 000, thereby making the proposed system capable of providing backup power for two simultaneous different voltage systems [24 VDC (Negative ground) and −48 VDC (Positive Ground)] simultaneously. In this dual voltage arrangement, positive and negative ends of each shelf's batteries are connected to corresponding buses represented in FIG. 5. Appropriate fuses or breakers are introduced at intermittent points to safeguard batteries and equipment in event of abnormal electrical signals. The −48V ground bus, 24V ground bus and cabinet ground studs are all separate with no interim connections. Cables are provided to connect to cabinet modules positioned above/below in the stacked configuration or to the load for power consumption at either voltage. In all cabinet and voltage configurations the cabinet module proposed herein connects to a single common earth-ground ring for low cost and ease of installation.

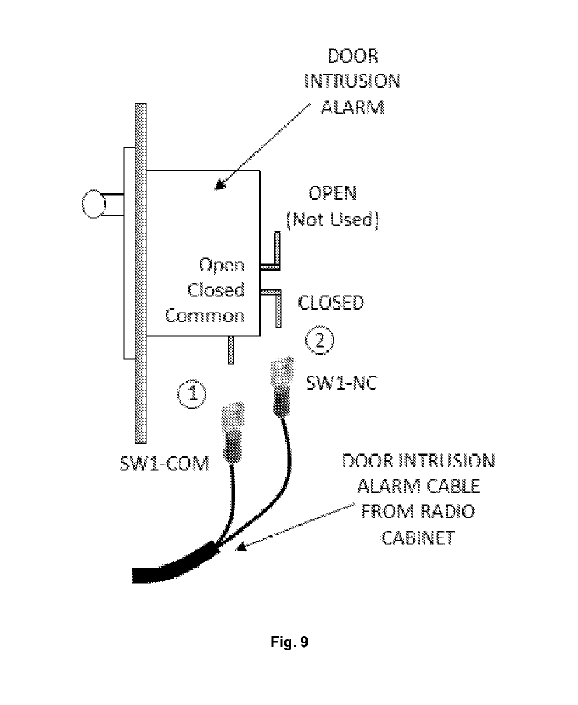

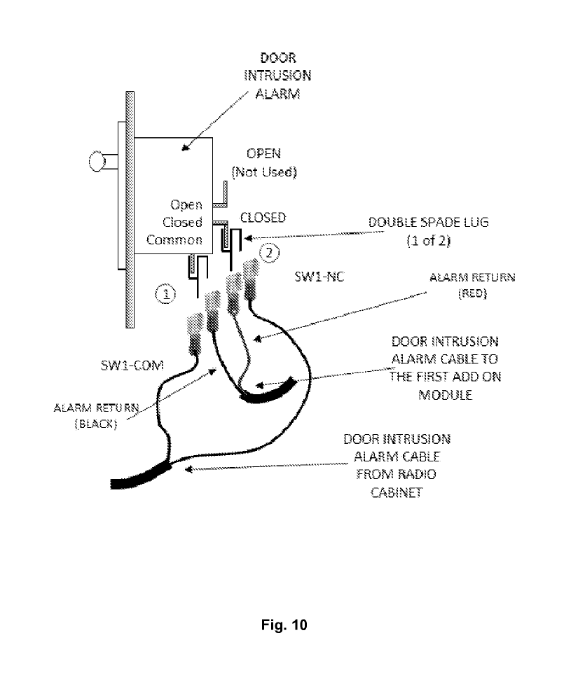

Mounted directly on a concrete surface or on a steel mounting plinth, the base module 000#1 and/or subsequent tiers on top of module 000#1 bear inputs for powering the batteries (+24 VDC and/or −48 VDC), fans (−48 VDC or 24 VDC), AC heater (110/220 AC) and outputs battery backup (+24 VDC and/or −48 VDC) and alarm outputs. FIG. 5(a) for battery breaker/fuse relay and/or FIG. 8 for fan malfunction and FIG. 9 and FIG. 10 for intrusion detection.

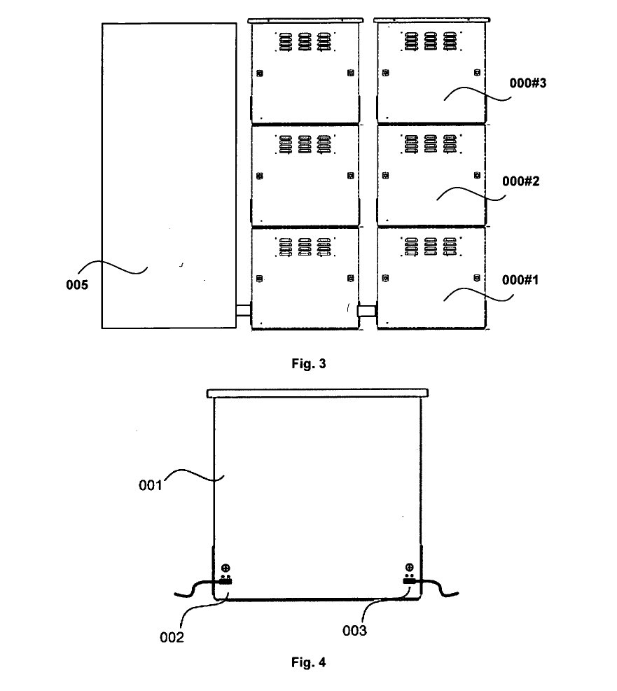

From an installation perspective, modules are stacked vertically up to a typical three tier configuration (000 #1, 000 #2 and 000 #3) thereby allowing for installation of large capacity batteries which are shipped separately. Dimensions of module (000) are arranged as per storage requirements without parting from principles of the present invention. In the preferred embodiment, wherein module (000) is to house eight, 12 VDC110/170/190/200 or other series batteries, the module (000) is made to have dimensions of 28.45 cm×28.45 cm×28.45 cm. As the modules are stacked, the width and depth remain same, however height increases multiplicatively as per tier reached. Conversely, there is no limit for horizontal growth, that is, number of base modules (000) that can be installed beside one another on the ground surface. FIG. 3 illustrates scheme of implementation of the unit enclosure in accordance with the present invention in a 2×3 stacked configuration. Optional embodiments are intended wherein the number of vertical tiers could be more or less depending mainly on dimensions of individual modules (000) and physical limits to formation of a stably stacked column using the high strength steel core skeleton interlocking it to additional cabinetry by interlocking and connecting additional high strength steel core skeletons directly a top and locked to each other. The present inventor contemplates further embodiments of the present invention in which the high strength steel cores, plurality of fastening/bolting points between adjoining modules provide sufficient rigidity and weight centering required for stably stacking three tiers of cabinets (each containing 6 strings of 4 batteries per string) and beyond wherein very large/heavy batteries can be housed as per requirements of the user, possibly in a step-wise-manner, without compromising on safety, installation concerns and costs of labor associated otherwise with housing of such batteries.

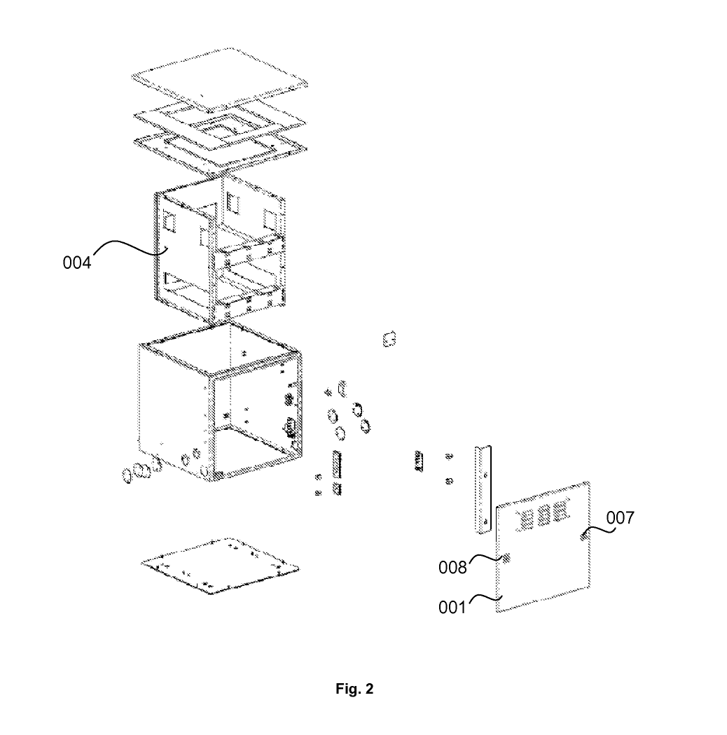

FIG. 2 illustrates internal construction and assembly of the enclosure in accordance with the present invention. As introduced hereinabove, each cabinet module represented by (000) encloses a chassis/core (004) bearing a plurality of shelves or trays for housing multiple batteries. The preferred embodiment provides up to 4-110/170/190/200 or other series batteries per shelf which are charged by the DC Bus (not shown in the drawings) located in the customer radio or rectifier cabinet 005. Cabinet 005 is connected to base module 000#1 via a 2-AWG (35 mm2) DC Cable. Alternative embodiments of the present invention are intended, wherein compartments of appropriate proportions may be provided to contain electronics other than batteries in the same cabinet.

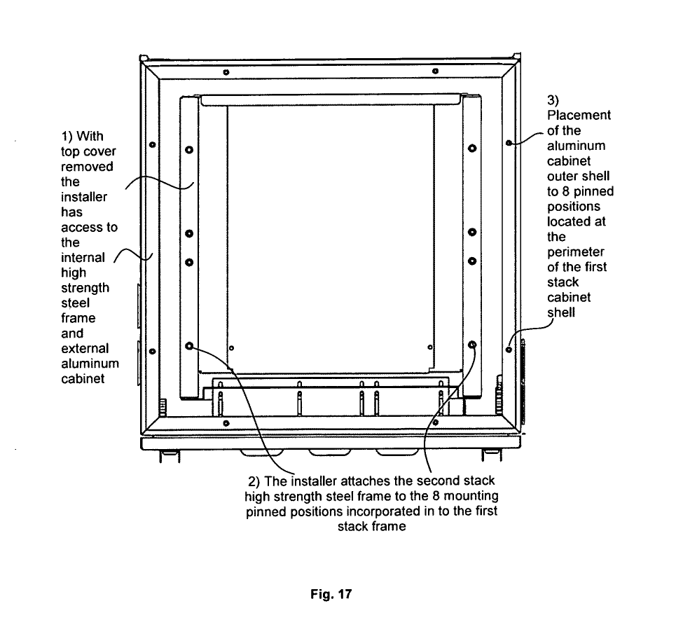

According to another aspect of the present invention, ability to stack cabinet modules represented by (000) FIG. 17 is enabled by interlocking between specific combination of linkers and lock-and-key profiles (not shown) articulated externally on docking structures within the walls of the cabinets. Once docked, the stacked modules are affixed via means such as nut bolts and threaded rivets and or riv-nuts. This tooling is within ambit of an unskilled layman, therefore, preserving the simplicity of design-attributed assemblage. FIG. 17 is a schematic for illustrating the connections and affixtures between enclosures stacked as shown in FIG. 3.

Integrated thermal/emissions management across the stacked configurations of modules represented by (000) is another inventive aspect of the present invention. Accordingly, accesses for electrical and mechanical interoperability are integrated into docking and peripheral (mating) walls of modules represented by (000) that allow assembly of cabinet modules in plural, yet preserve an airflow pattern necessary for evacuation of heat and chemicals dissipated by the batteries. The air flow pattern is characterized as a combination of active as well as passive currents occasioned by vents, conduits, heat exchangers and fans incorporated into and beneath peripheral walls of the battery cabinets the operational logic of which is intended to be covered in the present invention. In select alternative embodiments of the present invention, all cabinets in a stacked arrangement need not necessarily have cooling facilities. Heat management in such cabinets is passive with air flowing via conduits underneath peripheral walls of the cabinet modules.

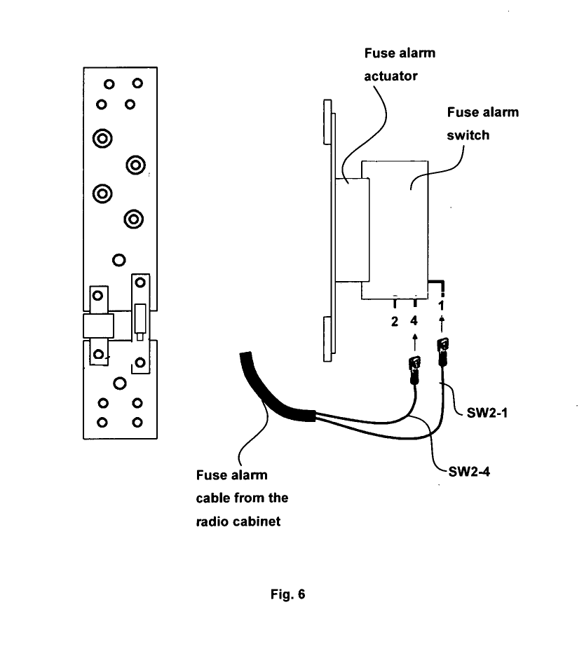

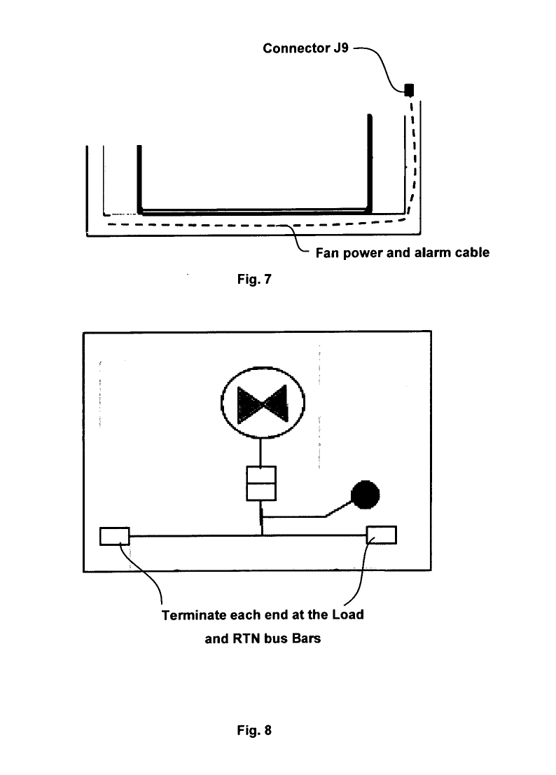

To ensure safety in operations, the module assembly described herein is provided with various alarms including those for fuse status, fan function temperature threshold, intrusion (hatch open) situations. Generally referring to FIGS. 5 to 10 that illustrates design of DC and return bus bars, routing and connection of signal cables for aforementioned features may be visualized as arranged for in module 000. The fan, temperature sensor, and cable are located on the front door hatch (001) within a pre-fitted harness (not shown in the drawings). For powering the heater pads (not shown in the drawings), AC cable is routed on the left side of the module 000, across the front and right side and finally up behind the DC bus with enough slack and anchoring to avoid pinching/stress during sweep of the hatch (001). Fan power and temperature sensor cable are routed along the bottom of the module from the left to the right side, and up the inside right behind the Hot DC bus. The fuse, fuse alarm actuator and switch are installed on the return bus while the corresponding alarm cables from the radio cabinet 005 are routed and connected as shown in said figures along with placement of thermal probes and their cables. Similarly, connections of said safety provisions are made to second and subsequent overhead modules via copper bus bars connecting the corresponding return bus bars. FIG. 6 is a schematic for illustrating routing and attachment of the fuse alarm cable to the fuse alarm switch in the module 000#1. FIG. 7 is a schematic for illustrating routing of the fan power cable in the hatch of module 000#1. FIG. 8 is a schematic for illustrating routing of fan power and temperature sensor cable in the hatch of module 000#1. FIG. 9 is a schematic for illustrating routing and attachment of the intrusion alarm cable to the alarm switch in the module 000#1. FIG. 10 is a schematic for illustrating routing and attachment of the intrusion alarm cable to the alarm switch for module 000#2.

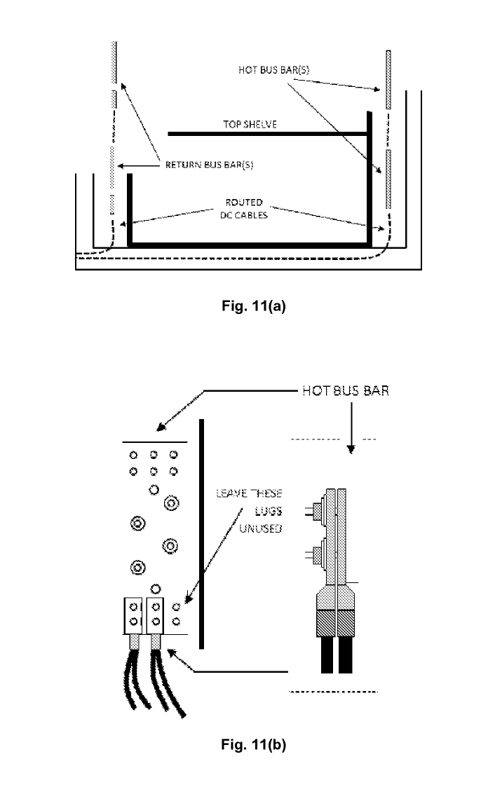

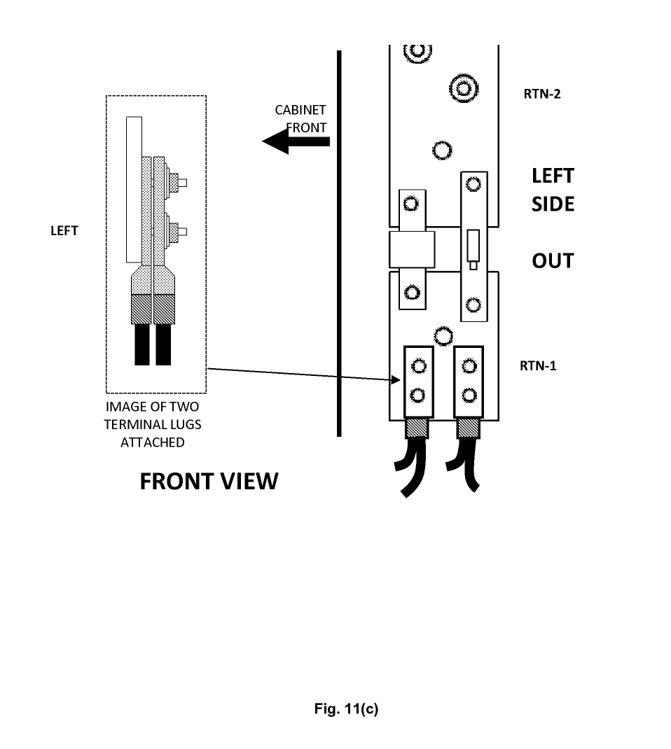

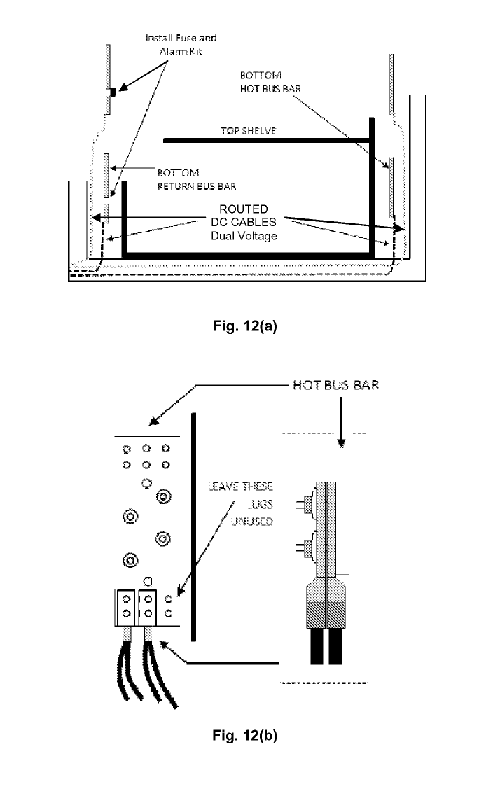

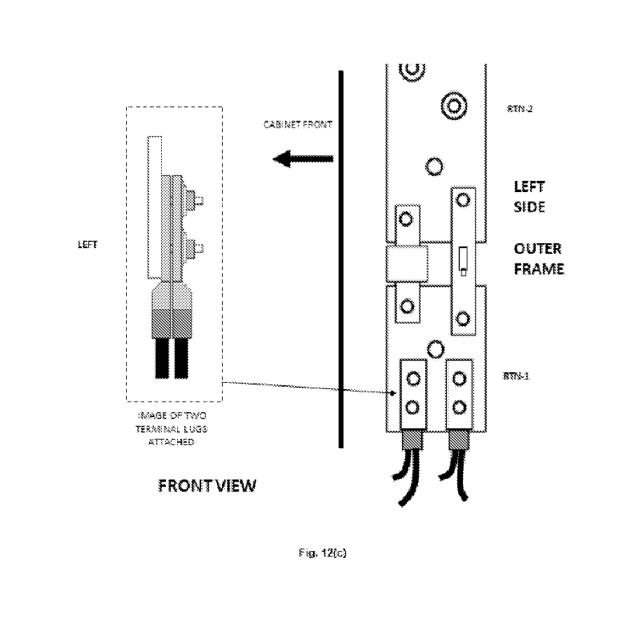

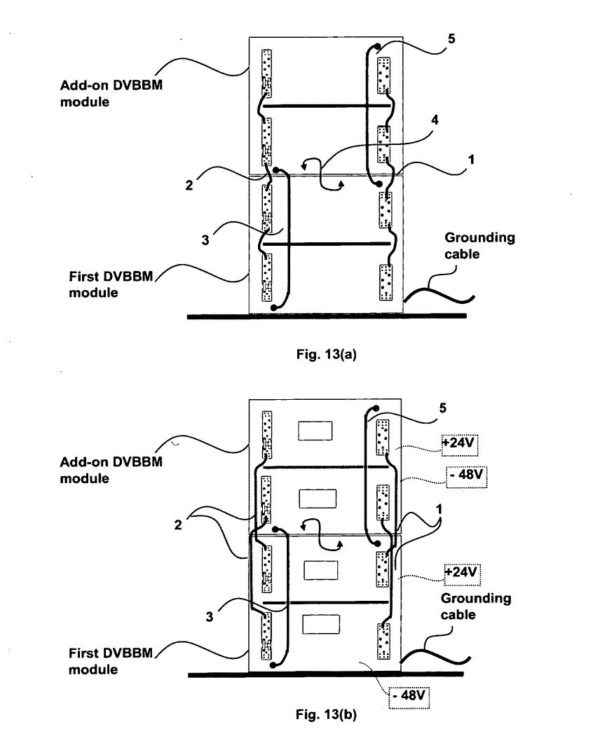

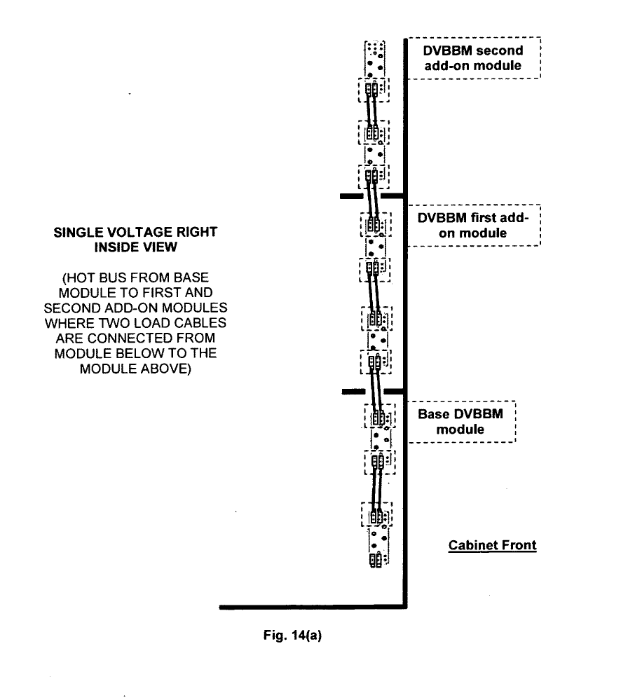

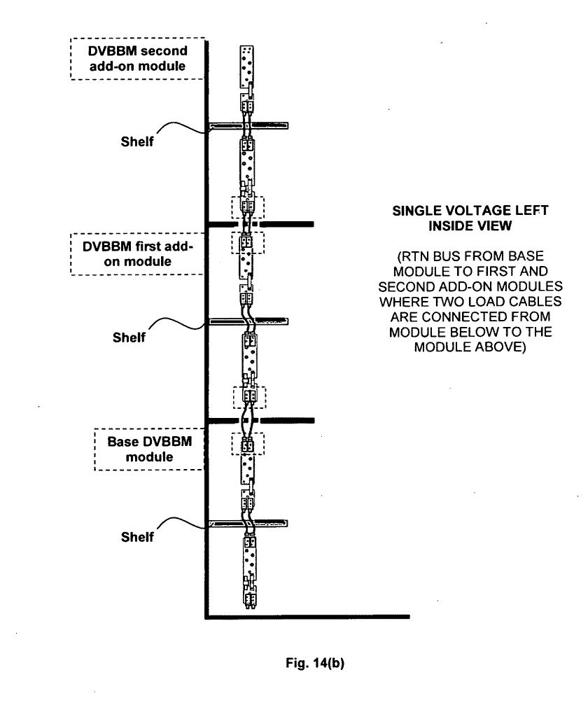

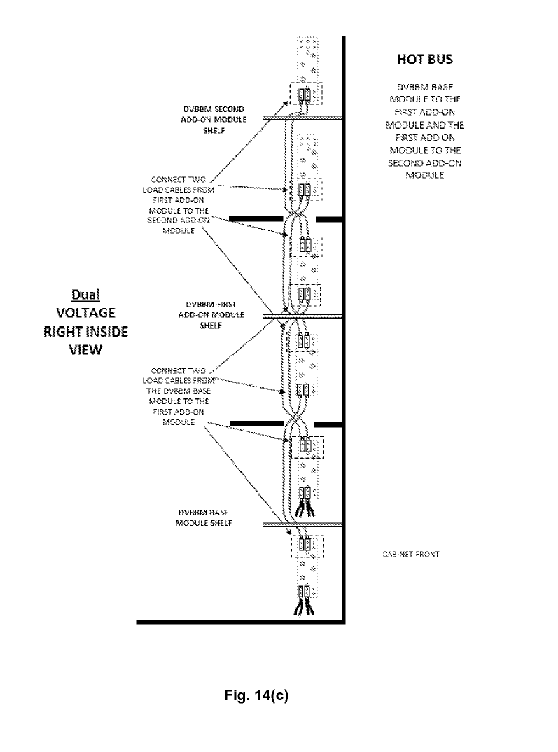

According to yet another aspect of the present invention, the simultaneous dual voltage capability provided for in the proposed battery cabinet design follows multiple configurations among:
a) +24V OR −48V (same voltage) for both shelves of a single cabinet module 000 [as shown in FIGS. 11 (a to c)]
b) +24V for one shelf AND −48V for the other shelve of a single cabinet module 000 as required by the user. [as shown in FIG. 12 (a to c)]
c) +24V or −48V on either shelf of cabinet module 000, and another or more cabinet modules, that mirror the first module and when stacked, add up to the power requirements of the user in a step-wise manner. [as shown in FIG. 13(a) for double stack and 14 (a and b) for triple stack columns]
d) +24V on both shelves of a single cabinet module 000 and −48V for both shelves of another cabinet module stacked above, or visa-versa, and another module above that mirrors either of the cabinets below to support the simultaneous power requirement for the user. [as shown in FIGS. 13(b) and 14(c and d)]

FIGS. 11(a to c) and 12(a to c) illustrate routing and return of DC power cable and configuration of bus bar connections respectively for configurations referred above. FIGS. 13 (a to b) illustrate DC and return bus interconnections between modules 000#3, 000#2 and 000#1 in a single voltage configuration while FIGS. 14 (c to d) illustrate DC and return bus interconnections between modules 000#3, 000#2 and 000#1 in a simultaneous dual voltage configuration.

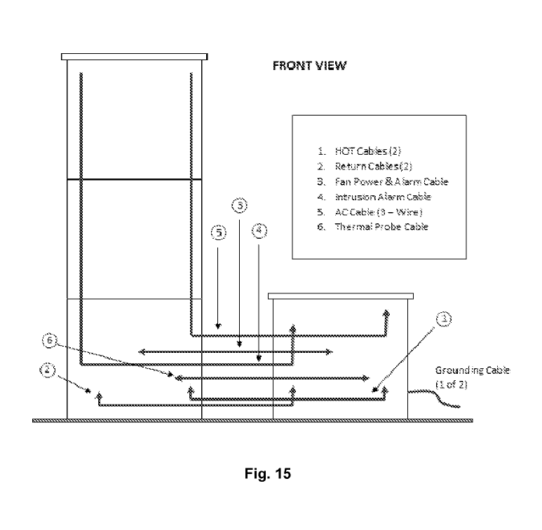

According to another aspect of the present invention, bus interconnections are arranged between 000#1 and 000#2 and/or from 000#3 and 000#2 to 000#1 in a manner capable of allowing the above voltage configurations in an embodiment of the present invention wherein the modular enclosures 000 are stacked in a three tier arrangement. FIGS. 13(a) and 13(b) are schematics for illustrating interconnections from module 000#1 and 000#2 in single voltage and simultaneous dual voltage configurations respectively. FIGS. 14(a) and 14(c) are schematics for illustrating right side internal schematic views for illustrating DC interconnections from 000#3 and 000#2 to 000#1 in single voltage and dual voltage configurations respectively. FIGS. 14(b) and 14(d) are schematics for illustrating left side internal schematic views for illustrating DC interconnections from 000#3 and 000#2 to 000#1 in single voltage and simultaneous dual voltage configurations respectively. This arrangement of connections is then linked to adjoining stack for continuing the simultaneous dual voltage functionality explained above. FIG. 15 is a schematic for illustrating the wiring overview of interconnections from 000#3 and 000#2 to 000#1 of one stack to 000#1 of adjoining stack.

The innovation of this invention fully integrates stack-ability and the delivery of power in an unlimited and unfettered manor. Current art is restricted in integrating stack-ability and power delivery by their very design. The end user saves money and enhances workplace safety by utilizing the innovative components of this invention.

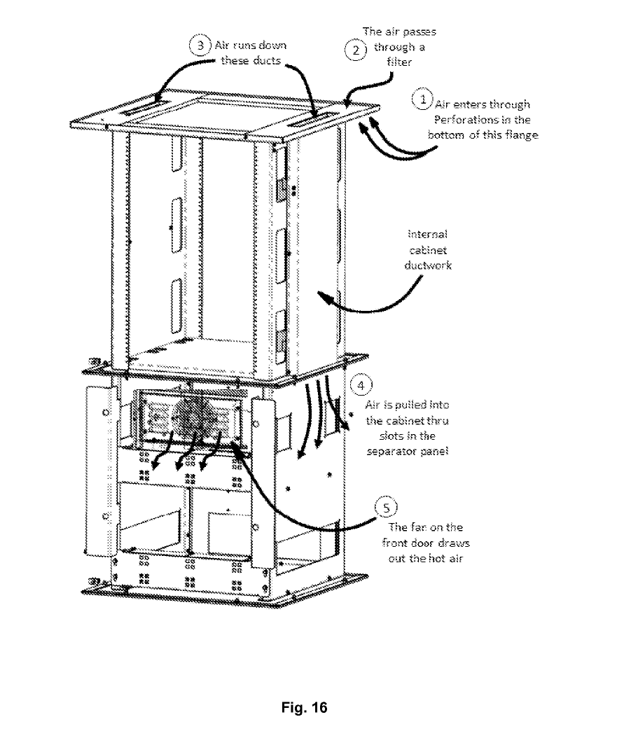

Provision of selective airflows for comprising a dynamic heat sink is another inventive aspect of the present invention. FIG. 16 is a schematic for illustrating the airflow pattern intended for thermal management of the stack shown in FIG. 3. As seen from this schematic, influx of ambient air is made through perforations on bottom sides of flanges comprising the top face of module 000 and, passing through a filter to remove air-borne particulates, the clarified air flows through lateral ducts profiled into sides of module 000 and pulled into the interior spaces of the connected modules via slots in the separator panels. Optionally, these panels can be left in or taken out to enable respectively among a cabinet-specific isolated method OR an integrative method of thermal and/or emissions management. Exhaust fans attached to hatches of the modules act as airflow engines whereby the motion path of air is decided by drawing in ambient air from above to fill in the voids created by hot air being thrown out by action of the aforementioned fans. Heating pads custom-fitted to cabinets 000 are also provided which, in combination with the dynamic heat sink described above, allow for temperatures of the cabinets to be maintained, at all times, within acceptable limits set by the user.

Lateral benefits released from above described outfitted design of the proposed cabinet module are the dismissal of additional stacking formwork, ease in transport/assembly of unit cabinet modules through conventional hoists/lifts as well as substantial savings on footprint space of the battery plant so provided besides provisioning for dual voltage application, sustained product lifecycle and simplicity of unit replacements in event of damage in addition to enhanced workplace safety, reduction in costs of onsite safety programs and reductions in greenhouse gas emissions.

### Example 1

Wherein a telecommunications or other type user deploys a 24 VDC telecommunications system operating in a 24 VDC environment and requiring a 24 VDC back-up battery system, and then later deploys at the same site a second telecommunications system which operates on a −48 VDC environment and requiring a −48 VDC back-up battery system, either adds or modifies the inventors cabinet to the site to accommodate the simultaneous dual voltage requirements of the site.

### Example 2

Wherein a telecommunications or other type user has the requirement to install telecommunications equipment onto a rooftop in a dense urban environment such as New York City and determining that it is too costly, to dangerous, to labor intensive, and having the requirement to close down roads and alleys to bring in heavy lifting cranes to hoist heavy battery cabinets and telecommunication equipment to the rooftop making the project prohibitive. Now having the inventor's cabinet enclosure can be disassembled locally, hand carried to the rooftop and reassembled in place and then adding the needed modules and batteries one-at-a-time to the newly constructed modular enclosure allows the telecommunications provider the ability to deploy such a site easily, safely, and economically regardless of the sites current or future power or equipment needs.

### Example 3

Wherein a telecommunications or other type user has the requirement to install next generation telecommunications equipment but has the need to continue the operation of the existing, legacy telecommunication equipment, and realizing that each of the telecommunications systems operate on a different voltage and having the need to back-up both systems simultaneously. Now, because of the inventors single foot print dual voltage modular cabinet has the ability to support simultaneous back-up for both voltages for the period of time necessary to install the new generation telecommunications equipment, the time to transition their customers to the new telecommunication equipment and the time necessary to dismantle the old legacy telecommunications equipment. Then having the flexibility and functionality to easily convert the inventor's battery cabinet from a simultaneous dual voltage design back to a single voltage design without loss or modification of the asset, footprint or physical removal or modification of the inventor's cabinet.

Thus there has been presented a simultaneous dual voltage battery base module having comprehensive integrated features in the manner and form described hereinabove. It is understood that the list given above and phraseology and terminology used is for purpose of illustration and description. They are not intended to be exhaustive or to limit the present invention to precise form mentioned above and obviously many modifications and variations are possible in light of above elaborations without departing from spirit and scope of the present invention. Ambit of the present invention is restricted only by the appended claims.

I claim:

1. A modular enclosure for housing electronic devices and power banks at a telecommunications site, said enclosure comprising a plurality of cabinet modules (000) characterized in having integrated means for allowing:
stacking to provide increasingly large storage capacity within a diminutive footprint;
provision of user-selectable backup power output among +24V and/or −48V in single voltage, simultaneous dual voltage and single voltage per shelf configurations;
ambient air-assisted integrated active management of the thermal profile of said modular enclosure;
ambient air-assisted passive management of the emission profile of said modular enclosure; and
detection and generation of alarm upon fault in the electrical I/O, the means for thermal and emissions management and in event of intrusion into any module (000) comprising said enclosure for housing electronic devices and power banks at a telecommunications site.

2. The modular enclosure of claim 1, wherein the stackable cabinet modules (000) each further comprise at least one top panel (010), a bottom panel (011), an outward opening front hatch (001) and three peripheral wall panels which together enclose a hollow external shell (009) within which a high-strength steel chassis (004) may be received for:
defining compartments sized according to the electronic devices and power banks to be housed; and
enclosing running void spaces adjoining inner walls of the external shell for ambient air-assisted thermal management of the modular enclosure (000)

3. The modular enclosure of claim 2, wherein the top panel (010) of each stackable cabinet (000) has outward surface artifacts mated for docking with bottom panel (011) of overhead cabinet module to assume a vertically stacked configuration.

4. The modular enclosure of claim 2, wherein the coupling between mated top (010) and bottom (011) panels of stacked cabinet modules is secured by means chosen among nut-bolts, threaded rivets, riv-nuts, their equivalents and their combinations.

5. The modular enclosure of claim 2, wherein the peripheral wall panels and hatch (001) have perforations for ventilation leading from the running void spaces between inner walls of the external shell (009) and chassis (004) to allow dissipation of internal heat buildup to the surroundings.

6. The enclosure according to claim 1, wherein the integrated means for managing thermal profile of said modular enclosure comprise interdependent operation of:
an exhaust fan affixed operatively to the hatch (001) of each stackable cabinet module which, when operated upon buildup of heat beyond a predefined limit, causes a draft of cool air to flow within the running void spaces between inner walls of the external shell (009) and chassis (004) of the cabinet module (000) thereby acting as a heat sink for dissipation of the excess heat within said modular enclosure;
a custom-fitted heating pad juxtaposed within the lumen of module (000) which, when operated upon lowering of temperature beyond a predefined limit, causes buildup of heat to acceptable levels in the cabinet module (000)
Wherein the limits of temperature for actuating the fan and/or the heating pad are user-selectable and triggered in response to logging of temperature data by thermal sensors communicatively dispersed among each cabinet module (000).

7. The enclosure according to claim 6, wherein heating and cooling functions are complementary due to the airflow being utilized reversibly as a heat and/or cold sink and further establish synergy in management of emissions by maintaining a positive pressure in the cabinet module (000).

8. The enclosure according to claim 1, wherein provision of user-selectable backup power output is enabled by implementing: among+24V and/or −48V in single voltage, simultaneous dual voltage and single voltage per shelf configurations is enabled by connections:
in case of same+24V OR −48V (same voltage) for both shelves of a single cabinet module 000 wherein the routing and return of DC power cable and configuration of bus bar connections are implemented as illustrated in FIGS. 11(a to c);
in case of +24V for one shelf AND −48V for the other shelve of a single cabinet module 000 as required by the user, wherein the routing and return of DC power cable and configuration of bus bar connections are implemented as illustrated in FIGS. 12(a to c);
+24V or −48V on either shelf of cabinet module 000, and another or more cabinet modules, that mirror the first module and when stacked, add up to the power requirements of the user in a step-wise manner, wherein the routing and return of DC power cable and configuration of bus bar connections are implemented as illustrated in FIG. 13(a) for double stack and 14 (a and b) for triple stack columns; and
+24V on both shelves of a single cabinet module 000 and −48V for both shelves of another cabinet module stacked above, or visa-versa, and another module above that mirrors either of the cabinets below to support the power requirement for the user, wherein the routing and return of DC power cable and configuration of bus bar connections are implemented as illustrated in FIGS. 13(b) and 14(c and d)

9. The enclosure according to claim 1, wherein each of the components comprising the cabinet module (000) are formed independently and assembled before installation on site.

10. The enclosure according to claim 1, wherein:
the means for detection and generation of alarm upon fault in electrical I/O is an electrical fuse;
the means for thermal and emissions management and event of intrusion are an electrical fuse, thermal sensor and electrical circuit

11. The enclosure according to claim 6, wherein the flow-through ventilation panels are left in place to prevent the air from passing between cabinet enclosures thereby isolating the thermal dynamics of each cabinet to itself thus resulting in an isolative cabinet-specific method of thermal and/or emissions management.

12. The enclosure according to claim 6, wherein the flow-through ventilation panels are removed to allow air to pass freely between the stacked cabinets thereby ventilating the adjacent cabinet stack and resulting in an integrative method of thermal and/or emissions management.
